(19) United States
(12) Patent Application Publication
(10) Pub. No.: US 2015/0200220 A1
(43) Pub. Date: Jul. 16, 2015

(54) IMAGE SENSING SYSTEM

(71) Applicant: Microsoft Corporation, Redmond, WA (US)

(72) Inventors: Andrew K. Juenger, Woodinville, WA (US); Prafulla Masalkar, Issaquah, WA (US)

(73) Assignee: Microsoft Corporation, Redmond, WA (US)

(21) Appl. No.: 14/155,281

(22) Filed: Jan. 14, 2014

(51) Int. Cl. H01L 27/146

(52) U.S. Cl. CPC H01L 27/14621; H01L 27/14627; H01L 27/14685

(57) ABSTRACT

Embodiments are disclosed that relate to image sensing systems configured to sense visible and infrared light. For example, one disclosed embodiment provides an image sensing system comprising an image sensor comprising a plurality of pixels, an optical path extending from an exterior of the image sensing system to the image sensor, and an infrared filter array positioned along the optical path. The infrared filter array is configured to transmit the infrared light to a first subset of pixels of the image sensor, and to filter at least a portion of the infrared light to reduce an amount of infrared light reaching a second subset of pixels of the image sensor relative to an amount of infrared light reaching the first subset of pixels.

### BACKGROUND

Imaging systems may be configured to detect electromagnetic radiation of a variety of different wavelengths. For example, some imaging systems may be configured to detect visible light for grayscale or color imaging. An image sensor used for color imaging may include an array of color filters configured to selectively filter light of various colors prior to the light reaching an image sensor. Other imaging systems may be configured to detect infrared light. Infrared imaging systems may utilize an infrared band pass filter to pass a desired wavelength band of infrared light to an image sensor while blocking other wavelengths.

### SUMMARY

Embodiments are disclosed that relate to image sensing systems configured to sense visible and infrared light. For example, one disclosed embodiment provides an image sensing system comprising an image sensor comprising a plurality of pixels, an optical path extending from an exterior of the image sensing system to the image sensor, and an infrared filter array positioned along the optical path. The infrared filter array is configured to transmit the infrared light to a first subset of pixels of the image sensor, and to filter at least a portion of the infrared light to reduce an amount of infrared light reaching a second subset of pixels of the image sensor relative to an amount of infrared light reaching the first subset of pixels.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows aspects of a computing environment in accordance with an embodiment of the disclosure.

FIG. 2 schematically illustrates light propagation through an image sensing system in accordance with an embodiment of the disclosure.

FIGS. 3-13 show various examples of image sensing systems in accordance with embodiments of the disclosure.

FIG. 14 shows a flowchart illustrating a method of manufacturing an image sensing system in accordance with an embodiment of the disclosure.

FIG. 15 shows a flowchart illustrating another method of manufacturing an image sensing system in accordance with an embodiment of the disclosure.

FIG. 16 shows a flowchart illustrating another method of manufacturing an image sensing system in accordance with an embodiment of the disclosure.

FIG. 17 shows a flowchart illustrating another method of manufacturing an image sensing system in accordance with an embodiment of the disclosure.

FIG. 18 shows a block diagram of a computing device in accordance with an embodiment of the disclosure.

### DETAILED DESCRIPTION

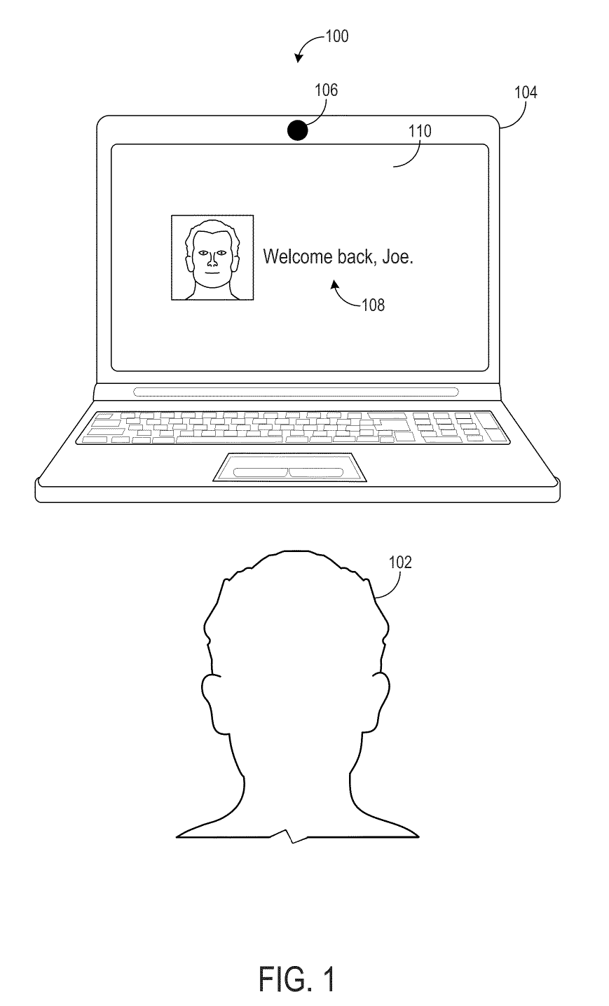

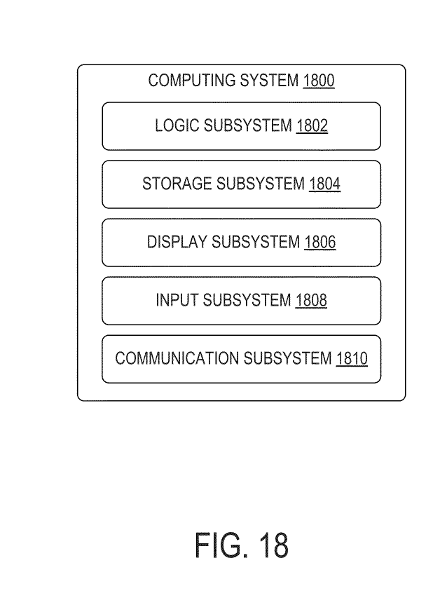

FIG. 1 shows an example environment 100 in which a user 102 is interacting with a computing device 104. While shown in this example as a laptop computing device, computing device 104 may take the form of any other suitable type of computing devices, including but not limited to other mobile device (e.g. a tablet computing device, smartphone, portable media player, etc.), a desktop computing device, server computing device, etc. Computing device 104 may include various subsystems, including but not limited to a logic subsystem that comprises one or more logic devices configured to execute instructions, and also a storage subsystem comprising one or more storage devices configured to store instructions executable by the logic subsystem to perform various computing device functions. Non-limiting example computing systems are described in more detail below with reference to FIG. 18.

Computing device 104 also comprises an image sensing system 106 that, for example, may collect image data regarding human subjects (e.g., user 102) within its field of view. Optical data including visible and infrared light collected by image sensing system 106 may be processed by computing device 104 to determine an identity of user 102. Upon identification of the user, a notification 108 conveying the determined identification of user 102 may be displayed on a display 110 of computing device 104. In other embodiments, the result of analysis performed on data captured by image sensing system 106 may be conveyed in non-visual manners (e.g., via audio, tactile feedback, etc.). Further, the image sensing system 106 also may be configured to capture data regarding inanimate objects and/or other features of its surrounding environment (e.g., environmental surfaces). In some embodiments, image sensing system 106 may be at least partially housed in an enclosure separate from that of computing device 104, and may be operatively coupled to the computing device via any suitable communication link. It will be understood that the identification of a user is but one of any number of uses for a computing device imaging system.

In some embodiments, image sensing system 106 may be configured to collect data regarding the depth of surfaces within its field of view in cooperation with other suitable components. For example, image sensing system 106 may include two image sensors arranged in a stereo configuration to obtain depth data. As another example, image sensing system 106 may include a depth camera system, such as a time-of-flight depth sensor and/or a structured light depth sensor.

Image sensing system 106 may collect visible and infrared light, which may be separately or cooperatively analyzed for the purposes described above. For example, data derived from infrared light captured by image sensing system 106 may be used to identify human subjects within its field of view, while data derived from visible light captured by the image sensing system may be fed to participants in a videoconferencing application.

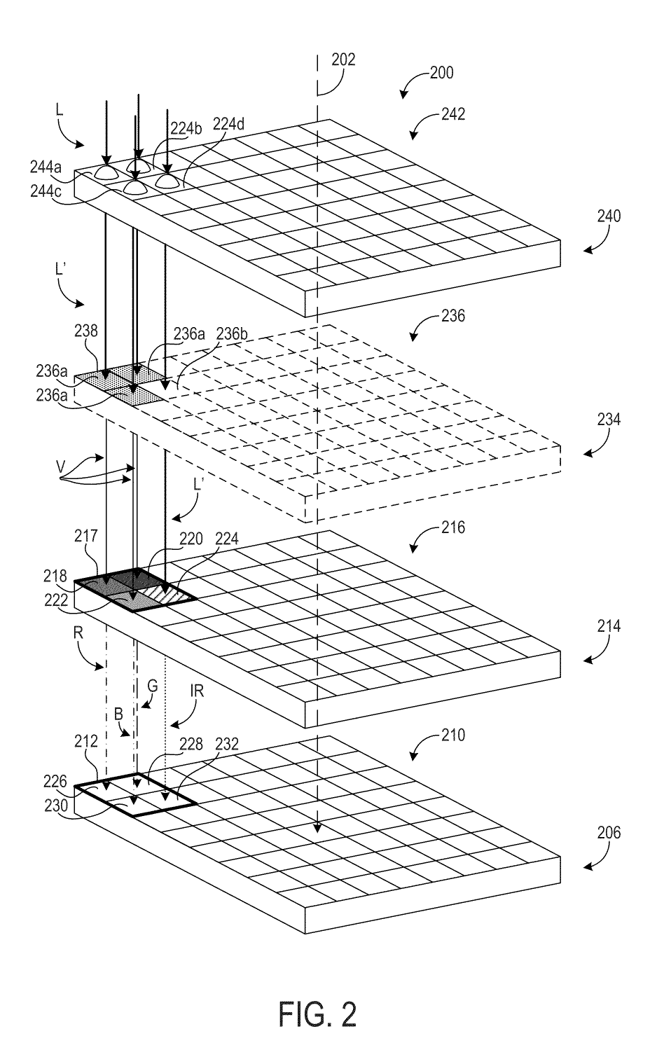

FIG. 2 shows a schematic depiction of an example image sensing system 200, and also a schematic depiction of light propagating through the image sensing system. Image sensing system 200 may form part of image sensing system 106 in FIG. 1, for example. The schematic representation of the various structures of the image sensing systems is shown for the purpose of illustration of various stages of the image sensing system 200, and is not intended to represent any particular physical implementation and/or any particular order of optical elements. Likewise, an imaging system may include other optics than those shown, including but not limited to other lenses.

Image sensing system 200 includes an optical path 202 extending from an exterior of the image sensing system to an image sensor 206. Image sensor 206, positioned at an end of optical path 202 is configured to convert certain wavelengths of incident light to electrical output. The electrical output may then be digitized for processing, analysis, and other tasks including the formation of two-dimensional images. Image sensor 206 may form part of a charge-coupled device (CCD) sensor or a complimentary metal-oxide semiconductor (CMOS) sensor, for example.

As shown, image sensor 206 includes a plurality of pixels 210 each being photosensitive to selected wavelengths of incident light. In the depicted example, the plurality of pixels 210 is arranged in a plurality of sensor tiles, one of which (sensor tile 212) is shown in FIG. 2. Each of the plurality of sensor tiles includes four pixels arranged in a two-by-two rectangular grid. As described in further detail below, each of the four pixels in a selected sensor tile 212 receives different wavelengths of light, including three that receive different colors of visible light and one that receives infrared light.

Also positioned along optical path 202 is a color filter array 214 that includes a plurality of color filters 216 each configured to transmit certain wavelengths of light (e.g., colors) while preventing the transmission of other different wavelengths of light. As with image sensor 206, the plurality of color filters 216 is arranged in a plurality of color filter tiles (e.g., color filter tile 217) such that each color filter tile of the color filter array corresponds to a corresponding sensor tile (e.g., sensor tile 212) of the image sensor. In this example, each color filter tile 217 of color filter array 214 includes three color filters each comprising one or more colorants (e.g. pigments and/or dyes) that facilitate the transmission of certain wavelengths of visible light. FIG. 2 also depicts an infrared band pass filter 224 configured to pass a band of infrared light and not color light to a corresponding infrared pixel of image sensor tile 212.

Each of the four pixels in each structure depicted in FIG. 2 may be designated herein by the type of light it passes or detects. For example, in color filter tile 217, a red color filter 218 is configured to transmit red wavelengths of light, a green color filter 220 is configured to transmit green wavelengths of light, a blue color filter 222 is configured to transmit blue wavelengths of light, and an infrared band pass filter 224 is configured to transmit selected wavelengths of infrared light. The pixels in image sensor 206 to which they respectively correspond may be referred to herein as a red pixel 226, a green pixel 228, a blue pixel 230, and an infrared pixel 232. In some embodiments, the infrared band pass filter 224 may be located in a different layer than the color filter array.

Also positioned along optical path 202 is an infrared filter array 234 configured to transmit infrared light to a first subset of pixels of image sensor, and to filter at least a portion of infrared light reaching a second subset of pixels of the image sensor relative to an amount of infrared light reaching the first subset of pixels. The first subset of pixels may correspond to infrared pixels 232 in image sensor 206, and the second subset of pixels may correspond to red pixels 226, green pixels 228, and blue pixels 230 (“the color pixels”) in the image sensor. In some embodiments, infrared filter array 234 also may filter at least a portion of visible light reaching the first subset of pixels, relative to an amount of visible light reaching the second subset of pixels.

Thus, color filter array 214 and infrared filter array 234 divide image sensor 206 into a plurality of image sensor tiles. In this configuration, each image sensor tile 212 includes three color pixels 226, 228, and 230, and an infrared pixel 232 arranged in a two by two grid.

Infrared filter array 234 may include one or more materials that absorb or otherwise block the transmission of infrared light, such as infrared absorbing dyes, pigments, interference filters, etc. Such materials may be disposed in locations that correspond to and align with the color pixels of image sensor 206, and omitted from (or used in lesser quantities in) locations that correspond to infrared pixels 232 of the image sensor. Infrared filter array 234 may comprise filter cells 236 arranged as infrared filter tiles (e.g., infrared filter tile 238) such that each infrared filter tile corresponds to a corresponding color filter tile of color filter array 214 and a corresponding image sensor tile of image sensor 206. Thus, in this example, cells 236a in infrared filter tile 238 include the one or more infrared-blocking materials (represented in FIG. 2 via shading), as they correspond to the color pixels of image sensor 206, while cell 236b does not include the one or more infrared-blocking materials (or comprises a lesser quantity of such materials), as it corresponds to infrared pixel 232 of the image sensor.

Also arranged along optical path 202 is a microlens array 240 comprising a plurality of microlenses 242. Each microlens (e.g., microlens 244) in the plurality of microlenses 242 is configured to gather light incident on its surface and focus the incident light onto an associated pixel of image sensor 206. For example, microlenses 244a, 244b, 244c, and 244d respectively focus light onto pixels 226, 228, 230, and 232 of image sensor 206. In the depicted example, the plurality of microlenses 242 is optically transparent to at least a portion of visible and infrared wavelengths, but in other embodiments the microlens array may have one or more filter materials incorporated into a bulk material of the microlenses. The plurality of microlenses 242 may be formed from any suitable material, including but not limited to various polymers, such as poly(methyl methacrylate) (PMMA). It will be appreciated that in some embodiments microlens array 240 may be omitted from image sensing system 200 without departing from the scope of this disclosure.

FIG. 2 also schematically depicts light propagating through image sensing system 200. It will be appreciated that this schematic depiction is provided as an example and is not intended to be limiting in any way. Certain aspects of the schematic depiction are exaggerated for the purpose of illustration. Further, as mentioned above and as described in more detail below, the various optical elements of image sensing system 200 may be arranged in different orders that that shown in FIG. 2.

As depicted, light L upstream of the microlens array 240 is focused by the microlens array 240 into light L′, wherein each microlens focuses light onto a corresponding image sensor pixel. Light L′ from the microlens array passes through the infrared filter array 234, where cells 236a remove at least a portion of the infrared component from light intended for the color pixels of the image sensor system (indicated as visible light V), while more infrared light is transmitted through cells that do not include infrared-blocking materials (e.g., cell 236b).

Visible light V then passes through the color filter array 214, while light L′ passes through infrared band pass filter 224 (which may be in any other suitable layer than that shown in FIG. 2), such that any visible light component of light L′ is blocked and desired wavelengths of infrared light are transmitted. In this manner, red, green, blue, and infrared light are incident on the corresponding pixels of image sensor tile 212. Image sensing system 200 thus facilitates the separate and simultaneous sensing of visible and infrared light.

The filtering of infrared light prior to the infrared light reaching the color pixels of the image sensor may offer advantages over exposing the color pixels to both color and infrared light and then electronically correcting for the infrared exposure of the color pixels. For example, a higher signal-to-noise ratio may be achieved via filtering of infrared light as compared to the computational correction of a color pixel value that was also exposed to infrared light.

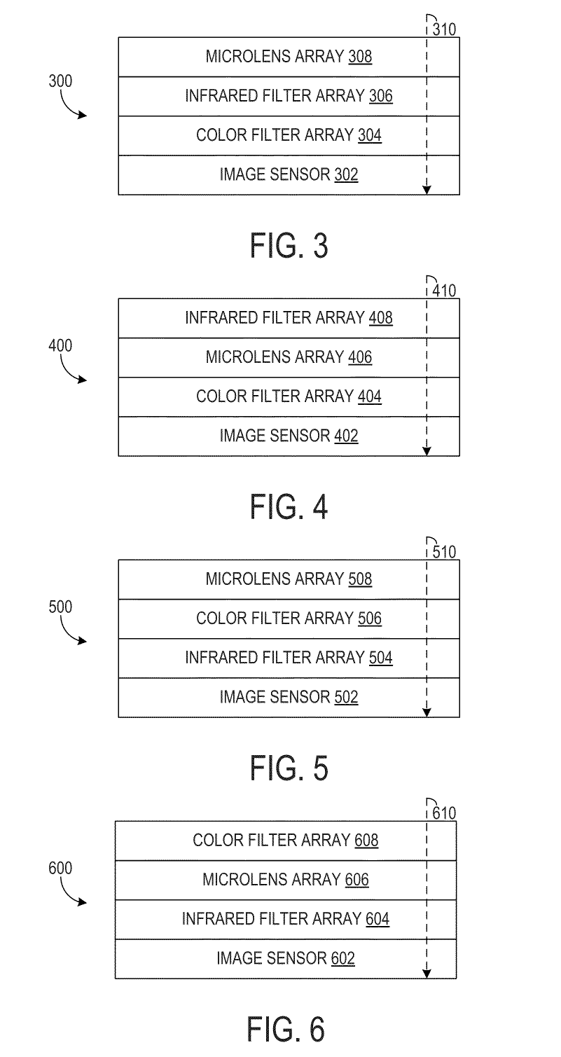

As mentioned above, the optical elements depicted in FIG. 2 may be arranged in any suitable order. FIGS. 3-13 show non-limiting examples of arrangements of the optical elements of FIG. 2. The image sensor, color filter array, infrared filter array, and microlens arrays shown in FIGS. 3-8 may respectively correspond to image sensor 206, color filter array 214, infrared filter array 234, and microlens array 240 of image sensing system 200 in FIG. 2, for example.

First, FIG. 3 shows an example image sensing system 300 including an image sensor 302, a color filter array 304 positioned above the image sensor, an infrared filter array 306 positioned above the color filter array, and a microlens array 308 positioned above the infrared filter array, all arranged along an optical path having a direction indicated by arrow 310. In this configuration, color filter array 304 may comprise a separate layer from infrared filter array 306 and microlens array 308

FIG. 4 shows another example image sensing system 400 including an image sensor 402, a color filter array 404 positioned above the image sensor, a microlens array 406 positioned above the color filter array, and an infrared filter array 408 positioned above the color filter array, all arranged along an optical path having a direction indicated by arrow 410. In contrast to image sensing systems 200 and 300, the microlens array 406 is positioned closer to the image sensor 402 than the infrared filter array 408. The infrared filter array 408 may be formed on a surface of microlens array 406, e.g. via lithographic techniques.

FIG. 5 shows another example image sensing system 500 including an image sensor 502, an infrared filter array 504 positioned above the image sensor, a color filter array 506 positioned above the infrared filter array, and a microlens array 508 positioned above the color filter array, all arranged along an optical path 510. In contrast to the image sensing systems described above, the color filter array 506 is positioned farther from the image sensor 502 than the microlens array 506.

FIG. 6 shows an example image sensing system 600 including an image sensor 602, an infrared filter array 604 positioned above the image sensor, a microlens array 606 positioned above the infrared filter array 604, and a color filter array 608 positioned above the microlens array. Layers 602, 604, 606, and 608 are arranged along optical path 610. Infrared filter array 604 may be formed on a surface of image sensor 602 or a surface of microlens array 606 closes to image sensor 602, and color filter array 608 is located father from image sensor 602 than microlens array 606. Color filter array 608 may be formed as a layer on microlens array 604, or formed as a separate layer.

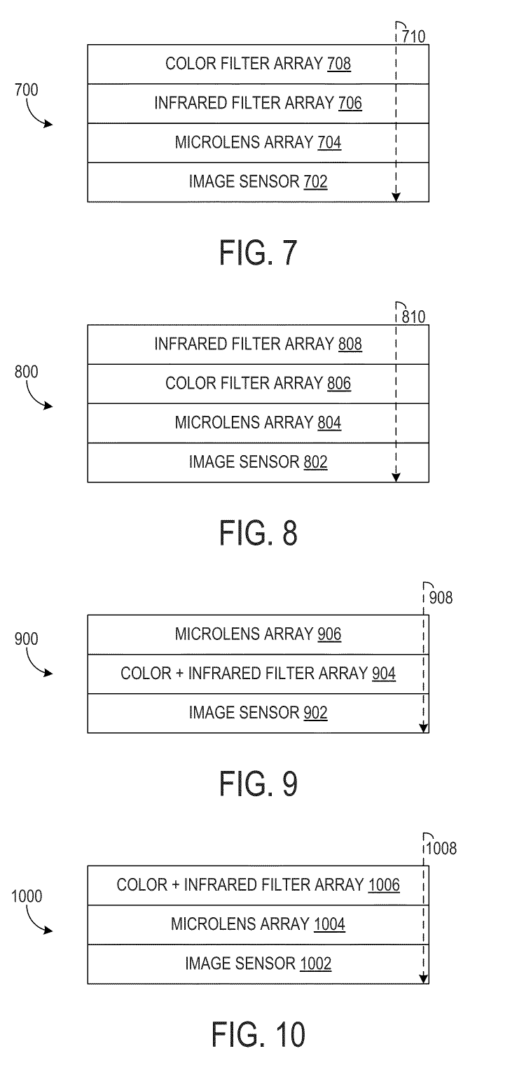

FIG. 7 shows an example image sensing system 700 including an image sensor 702, a microlens array 704 positioned above the image sensor, an infrared filter array 706 positioned above the microlens array, and a color filter array 708 positioned above the infrared filter array, all arranged along an optical path 710. FIG. 8 shows an example image sensing system 800 including an image sensor 802, a microlens array 804 positioned above the image sensor, a color filter array 806 positioned above the microlens array, and an infrared filter array 808 positioned above the color filter array, all arranged along an optical path 810. In these embodiments, infrared filter array 706 and/or color filter array 708 may be formed on a surface of microlens array 704, or formed as a separate structure.

In some embodiments, two or more of the optical components of FIG. 2 may be combined into a single structure. FIGS. 9-15 show example embodiments in which the infrared filter array is combined with other optical components in a common structure. First, FIG. 9 shows an example image sensing system 900 including an image sensor 902, a combined color and infrared filter array 904 positioned above the image sensor, and a microlens array 906 positioned above the combined color and infrared filter array. Layers 902, 904, and 906 are all positioned along a common optical path 908. In this example, infrared absorbing materials are mixed with one or more colorants used form the color filters, such that color and infrared filtering occurs in a same layer. The materials may be pre-mixed and then deposited, for example, via a lithographic patterning process or other suitable process. FIG. 10 shows a similar imaging system, except that the combined color and infrared filter array 1006 is positioned farther from an image sensor 1002 than a microlens array 1004 along an optical path 1008.

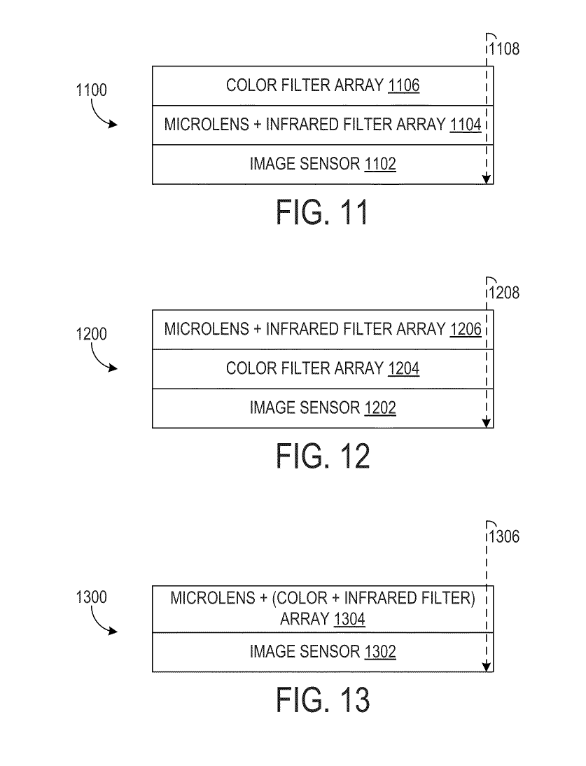

FIGS. 9 and 10 show embodiments in which the color filter and infrared filter materials are mixed together. In other embodiments, one or more filter materials may be mixed with a material from which the microlens array is formed. For example, FIG. 11 shows an example image sensing system 1100 including an image sensor 1102, a combined microlens and infrared filter array 1104 positioned above the image sensor, and a color filter array 1106 positioned above the combined color and infrared filter array along an optical path 1108. In this example, one or more infrared blocking materials are incorporated into a bulk of a microlens array to form combined microlens and infrared filter array 1104. For example, an infrared-absorbing dye or pigment may be added to a curable material that is then deposited and cured to form the microlens array. FIG. 12 shows a similar image sensing system 1200, except that the combined microlens and infrared filter array 1206 is positioned farther from an image sensor 1202 than a color filter array 1204 along an optical path 1208.

FIG. 13 shows an example in which the color and infrared filer array are both integrated with the microlens array into a combined microlens, color filter, and infrared filter array 1304, shown positioned in front of an image sensor 1302 along an optical path 1306. In such an example, the color filter materials and infrared filter material(s) each may be mixed with a curable material from which the microlens array is formed. Then, the microlens/filter materials for each color filter and the infrared filter array may be deposited separately in a suitable patterning process to form the microlens array.

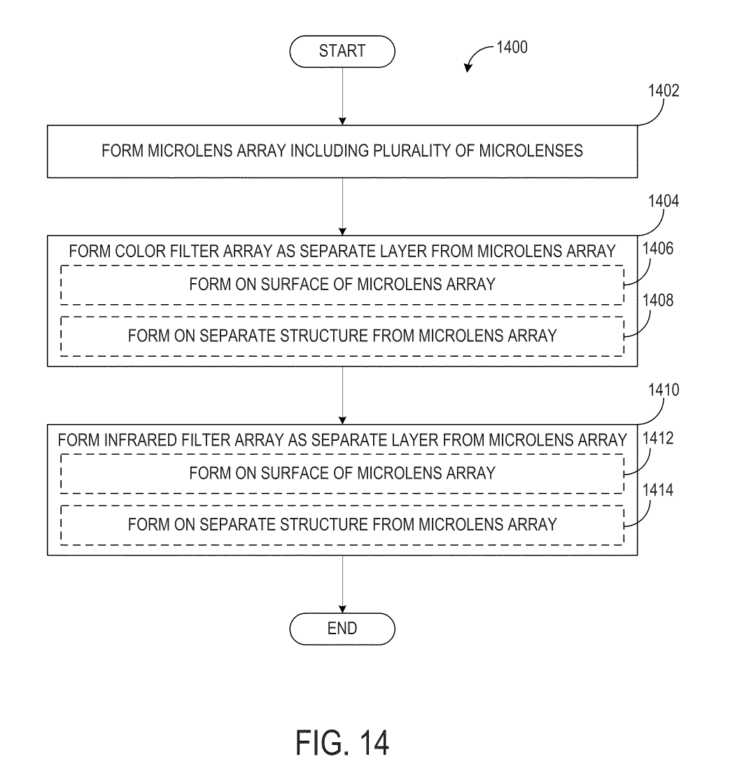

FIG. 14 shows a flow diagram illustrating a method 1400 of manufacturing an image sensing system in accordance with an embodiment of this disclosure. Method 1400 may be used to manufacture part of image sensing system 1000 shown in FIG. 10, for example. At 1402, method 1400 comprises forming a microlens array including a plurality of microlenses. Next, at 1404 of method 1400, a color filter array is formed, for example, on a surface of the microlens array (as indicated at 1406) or as a separate structure (as indicated at 1408). The color filter array may comprise one or more colorants mixed in a suitable polymer matrix (e.g. a PMMA matrix), or may have any other suitable structure.

Next, at 1410, method 1400 comprises forming an infrared filter array as a layer separate from the microlens array. Forming the infrared filter array may include, at 1412, forming the infrared filter array on a surface of the microlens array. Alternatively, formation of the infrared filter array may include, at 1414, forming the infrared filter array on a structure separate from that of the microlens array.

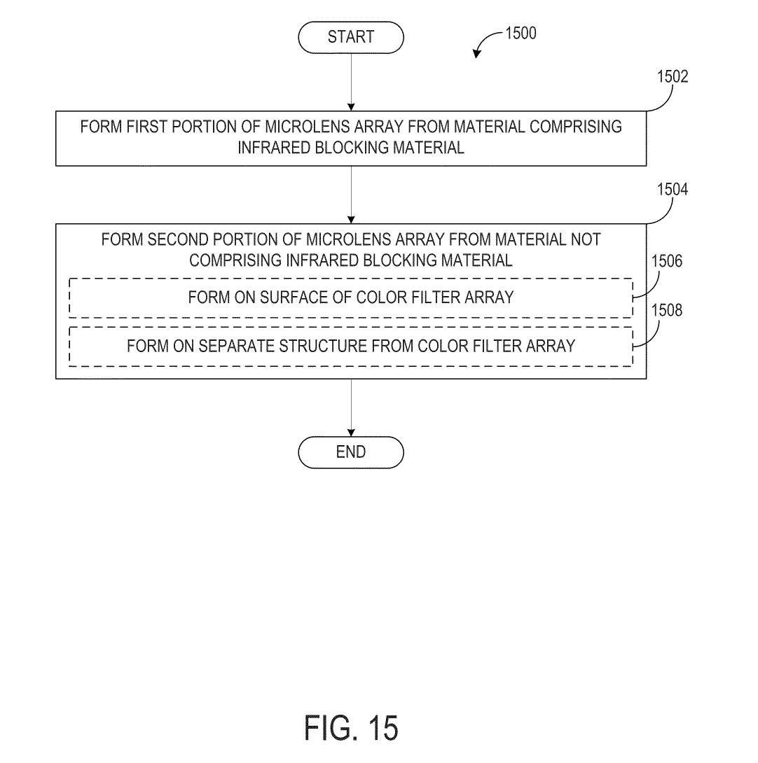

FIG. 15 shows a flow diagram illustrating another embodiment of a method 1500 of manufacturing an image sensing system in accordance with an embodiment of this disclosure. At 1502, method 1500 comprises forming a first portion of a microlens array from material comprising an infrared blocking material.

Next, at 1504, method 1500 comprises forming a second portion of the microlens array from material that does not comprise the infrared blocking material, or comprises a lesser concentration of infrared blocking material than the first portion. Forming the second portion may include, at 1506, forming the microlens array on a surface of a color filter array. Alternatively, formation of the second portion may include, at 1508, forming the microlens array on a structure separate from the color filter array.

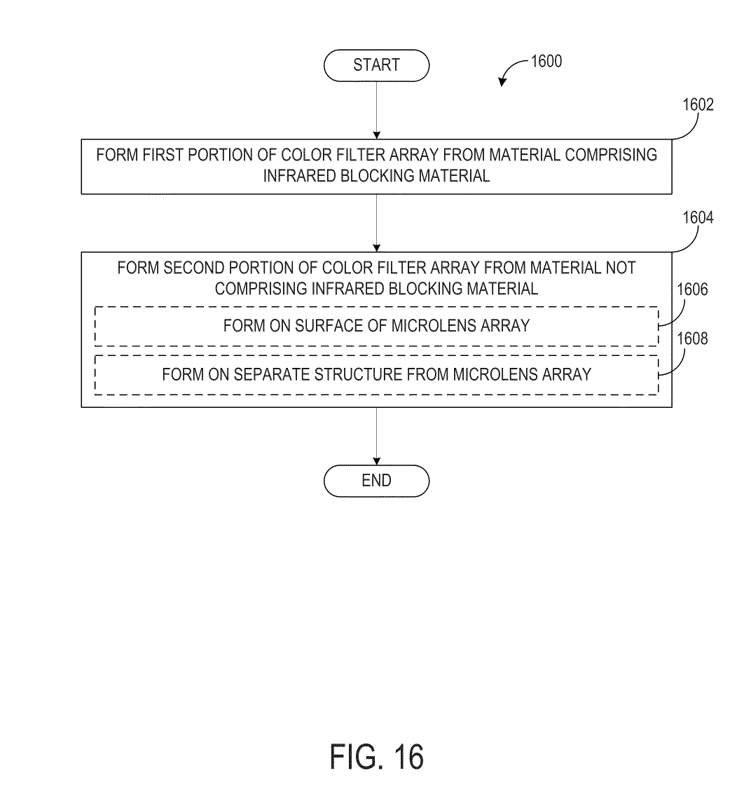

FIG. 16 shows a flow diagram illustrating another embodiment of a method 1600 of manufacturing an image sensing system in accordance with an embodiment of this disclosure. At 1602, method 1600 comprises forming a first portion of a color filter array from a material comprising an infrared blocking material. Next, at 1604, method 1600 comprises forming a second portion of the color filter array is formed from material that does not comprise the infrared blocking material. Forming the second portion may include, at 1606, forming the color filter array on a surface of a microlens array, or at 1608, forming the color filter array on a structure separate from the microlens array.

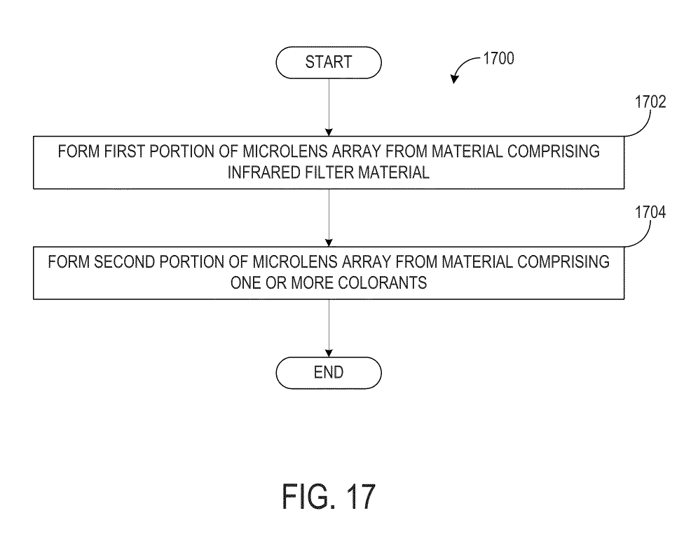

FIG. 17 shows a flowchart illustrating a yet another embodiment of a method 1700 of manufacturing an image sensing system in accordance with an embodiment of this disclosure. At 1702, method 1700 comprises forming a first portion of a microlens array from material comprising an infrared filter material. The infrared filter material may comprise at least one infrared blocking material. Further, at 1704, method 1700 comprises forming a second portion of the microlens array from material comprising one or more colorants (e.g. color filter materials). In some embodiments, microlens material may be mixed separately with each color filter material, and each color may be deposited in a separate patterning step.

In some embodiments, an RGB image sensing system that is configured to sense visible light may comprise an infrared filter layer (e.g. an infrared cut filter) positioned along the optical path to filter at least a portion of the infrared light. Such a filter may be provided as a separate structure and at an incremental cost in such image sensors. Thus, to reduce a cost of an image sensing system, the IR cut filter material may be included in another layer of the image sensing system, such as a color filter layer or microlens array, e.g. by mixing the infrared blocking materials of the infrared filter layer with materials used to form the color filter array and/or the microlens array, as described above. This may help to reduce the cost of an RGB image sensing system.

The image sensing systems embodiments disclosed herein and the embodiments of methods of making image sensing systems may be used in, and/or to form, any suitable type of device. FIG. 18 schematically shows a non-limiting embodiment of a computing system 1800 that may incorporate the image sensing system embodiments described above. Computing system 1800 is shown in simplified form. Computing system 1800 may take the form of one or more personal computers, server computers, tablet computers, home-entertainment computers, network computing devices, gaming devices, mobile computing devices, mobile communication devices (e.g., smart phone), and/or other computing devices.

Computing system 1800 includes a logic subsystem 1802 and a storage subsystem 1804. Computing system 1800 may optionally include a display subsystem 1806, input subsystem 1808, communication subsystem 1810, and/or other components not shown in FIG. 18.

Logic subsystem 1802 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage subsystem 1804 includes one or more physical devices configured to hold instructions executable by the logic machine to implement the methods and processes described herein. When such methods and processes are implemented, the state of storage subsystem 1804 may be transformed—e.g., to hold different data.

Storage subsystem 1804 may include removable and/or built-in devices. Storage subsystem 1804 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 1804 may include volatile, nonvolatile, dynamic, static, read/write, read-only, random-access, sequential-access, location-addressable, file-addressable, and/or content-addressable devices.

It will be appreciated that storage subsystem 1804 includes one or more physical devices. However, aspects of the instructions described herein alternatively may be propagated by a communication medium (e.g., an electromagnetic signal, an optical signal, etc.) that is not held by a physical device for a finite duration.

Aspects of logic subsystem 1802 and storage subsystem 1804 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1806 may be used to present a visual representation of data held by storage subsystem 1804. This visual representation may take the form of a graphical user interface (GUI). As the herein described methods and processes change the data held by the storage machine, and thus transform the state of the storage machine, the state of display subsystem 1806 may likewise be transformed to visually represent changes in the underlying data. Display subsystem 1806 may include one or more display devices utilizing virtually any type of technology. Such display devices may be combined with logic subsystem 1802 and/or storage subsystem 1804 in a shared enclosure, or such display devices may be peripheral display devices.

When included, input subsystem 1808 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition (including but not limited to the image sensing system embodiments described herein), a head tracker, eye tracker, accelerometer, and/or gyroscope for motion detection and/or intent recognition; as well as electric-field sensing componentry for assessing brain activity.

When included, communication subsystem 1810 may be configured to communicatively couple computing system 1800 with one or more other computing devices. Communication subsystem 1810 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 1800 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. An image sensing system configured to sense visible and infrared light, the image sensing system comprising:
an image sensor comprising a plurality of pixels;
an optical path extending from an exterior of the image sensing system to the image sensor; and
an infrared filter array positioned along the optical path, the infrared filter array being configured to transmit the infrared light to a first subset of pixels of the image sensor, and to filter at least a portion of the infrared light to reduce an amount of infrared light reaching a second subset of pixels of the image sensor relative to an amount of infrared light reaching the first subset of pixels.

2. The image sensing system of claim 1, further comprising a color filter array positioned along the optical path.

3. The image sensing system of claim 2, wherein the color filter array comprises a plurality of color filters comprising one or more colorants, and wherein the infrared filter array comprises one or more infrared blocking materials mixed with the one or more colorants of the color filter array.

4. The image sensing system of claim 2, wherein the color filter array comprises a separate layer of material from the infrared filter array.

5. The image sensing system of claim 2, wherein the infrared filter array is formed on a surface of a microlens array, the microlens array comprising a plurality of microlenses, each microlens being configured to focus light onto an associated pixel of the image sensor.

6. The image sensing system of claim 2, wherein the infrared filter array comprises an infrared blocking material incorporated into a bulk of a microlens array, the microlens array comprising a plurality of microlenses, each microlens being configured to focus light onto an associated pixel of the image sensor.

7. The image sensing system of claim 2, wherein the color filter array and the infrared filter array divide the image sensor into a plurality of tiles, each tile comprising three color pixels and an infrared pixel arranged in a two by two grid.

8. The image sensing system of claim 1, wherein the infrared filter array is further configured to filter at least a portion of the visible light to reduce an amount of visible light reaching the first subset of pixels relative to an amount of visible light reaching the second subset of pixels.

9. The image sensing system of claim 1, wherein the infrared filter array comprises an array of infrared blocking filters.

10. The image sensing system of claim 1, wherein the infrared filter array comprises an array of interference filters.

11. The image sensing system of claim 1, wherein the image sensing system is at least partially housed in a mobile computing device.

12. An image sensing system configured to sense visible and infrared light, the image sensing system comprising:
an image sensor comprising a plurality of pixels;
an optical path extending from an exterior of the image sensing system to the image sensor;
a microlens array comprising a plurality of microlenses, each microlens being configured to focus light onto an associated pixel of the image sensor;
an infrared filter array positioned along the optical path, the infrared filter array being configured to transmit the infrared light to a first subset of pixels of the image sensor, and to filter at least a portion of the infrared light to reduce an amount of infrared light reaching a second subset of pixels of the image sensor relative to an amount of infrared light reaching the first subset of pixels; and
a color filter array positioned along the optical path, the color filter array comprising a plurality of color filters comprising one or more colorants, the plurality of color filters being configured to transmit colors of the visible light to the second subset of pixels.

13. The image sensing system of claim 12, wherein the infrared filter array comprises one or more infrared blocking materials mixed with the one or more colorants of the color filter array.

14. The image sensing system of claim 12, wherein the infrared filter comprises an infrared blocking material incorporated into a bulk of the microlens array.

15. The image sensing system of claim 12, wherein the infrared filter array comprises a separate layer of material from the microlens array and the color filter array.

16. A method of manufacturing an image sensing system configured to sense visible and infrared light, the method comprising:
forming a microlens array comprising a plurality of lenses each configured to focus light onto a corresponding pixel of an image sensor;
forming an infrared filter array configured to transmit infrared light to a first subset of pixels of the image sensor and to filter at least a portion of the infrared light to reduce an amount of infrared light reaching a second subset of pixels of the image sensor relative to an amount of light reaching the first subset of pixels; and
forming a color filter array configured to filter different colors of light from reaching different pixels of the second subset of pixels of the image sensor.

17. The method of claim 16, wherein forming the infrared filter array comprises forming the infrared filter array as a separate layer from the color filter array.

18. The method of claim 16, wherein forming the infrared filter array and the color filter array comprises depositing a composition comprising one or more colorants and also an infrared blocking material.

19. The method of claim 16, wherein forming the infrared filter array comprises depositing the infrared filter array on the microlens array.

20. The method of claim 16, wherein forming the infrared filter array comprises forming the microlens array at least partially from a mixture comprising an infrared blocking material.
